(19) United States
(12) Patent Application Publication
(10) Pub. No.: US 2009/0008134 A1
(43) Pub. Date: Jan. 8, 2009

(54) Module

(76) Inventors: Michiaki Tsuneoka, Osaka (JP); Joji Fujiwara, Osaka (JP)

Correspondence Address: MCDERMOTT WILL & EMERY LLP, 600 13TH STREET, NW, WASHINGTON, DC, 20005-3096, US

(21) Appl. No.: 11/631,348

(22) PCT Filed: Aug. 24, 2006
(86) PCT No.: PCT/JP2006/316554

§ 371 Date: Dec. 29, 2006

(30) Foreign Application Priority Data
Sep. 2, 2005 (JP) 2005-254778

(51) Int. Cl. H05K 1/02

(52) U.S. Cl. 174/255

(57) ABSTRACT

A module includes a first multilayer wiring board, a second multilayer wiring board having an upper surface facing a lower surface of the first multilayer wiring board, a component mounted on an upper surface of the first multilayer wiring board, a first terminal electrode provided on the lower surface of the first multilayer wiring board, a second terminal electrode provided on the upper surface of the second multilayer wiring board and connected to the first terminal electrode, and a terminal electrode provided on a lower surface of the second multilayer wiring board. This module is manufactured at a preferable yield rate.

### TECHNICAL FIELD

The present invention relates to a module including a component mounted on a multilayer wiring board.

### BACKGROUND ART

Wireless communication devices, such as mobile phones, has been recently demanded to have small sizes. In order to meet this demand, modules used for the wireless communication devices needs to have small sizes and more functions.

FIG. 5 is a sectional view of conventional module 5001. In module 5001, surface-mounted component 103 is mounted onto a land pattern provided on a top surface of multilayer wiring board 101. Grounding electrodes 104 arranged at multiple positions on the top surface of multilayer wiring board 101 is connected to shield case 105. A bottom surface of multilayer wiring board 101 has terminal electrode 102 for external connection arranged thereon.

Inductors and capacitors are provided from patterns in an inner layer portion of multilayer wiring board 101 provides plural functional circuits, such as a filter and a balanced-unbalanced transformer. Functional circuits 107A and 107B are arranged laterally adjacently to each other in the inner layer portion of multilayer wiring board 101. Functional circuits 107A and 107B are separated to ensure isolation between them. Functional circuits 107A and 107C are arranged adjacently to each other in a thickness direction. Grounding surface 108 provided between functional circuits 107A and 107C prevents circuits 107A and 107C from electrically coupling to each other.

Multilayer wiring board 101 including a large number of functional circuits adjacent to each other in its thickness direction includes a large number of layers. In order to simultaneously satisfy desired characteristics of the functional circuits in board 101, module 5001 decreases its manufacturing yield.

### SUMMARY OF THE INVENTION

A module includes a first multilayer wiring board, a second multilayer wiring board having an upper surface facing a lower surface of the first multilayer wiring board, a component mounted on an upper surface of the first multilayer wiring board, a first terminal electrode provided on the lower surface of the first multilayer wiring board, a second terminal electrode provided on the upper surface of the second multilayer wiring board and connected to the first terminal electrode, and a terminal electrode provided on a lower surface of the second multilayer wiring board.

This module is manufactured at a preferable yield rate.

### BRIEF DESCRIPTION OF DRAWINGS

FIG. 1 is a sectional view of a module according to Exemplary Embodiment 1 of the present invention.

FIG. 2A is a top view of a multilayer wiring board of the module according to Embodiment 1.

FIG. 2B is a bottom view of the multilayer wiring board shown in FIG. 2A.

FIG. 2C is a top view of another multilayer wiring board of the module according to Embodiment 1.

FIG. 2D is a bottom view of the multilayer wiring board shown in FIG. 2C.

FIG. 3 is a sectional view of a module according to Exemplary Embodiment 2 of the invention.

FIG. 4A is a top view of a multilayer wiring board of the module according to Embodiment 2.

FIG. 4B is a bottom view of the multilayer wiring board shown in FIG. 4A.

FIG. 4C is a top view of another multilayer wiring board of the module according to Embodiment 2.

FIG. 4D is a bottom view of the multilayer wiring board shown in FIG. 4C.

FIG. 5 is a sectional view of a conventional module.

### REFERENCE NUMERALS

1A Multilayer Wiring Board (First Multilayer Wiring Board)
1B Multilayer Wiring Board (Second Multilayer Wiring Board)
3 Component
6A Terminal Electrode (First Terminal Electrode)
6B Terminal Electrode (Second Terminal Electrode)
9A Top Surface of Multilayer Wiring Board 1A (First Surface)
9B Bottom Surface of Multilayer Wiring Board 1A (Second Surface)
9C Top Surface of Multilayer Wiring Board 1B (Third Surface)
9D Bottom Surface of Multilayer Wiring Board 1B (Fourth Surface)
9E Exposing Portion
11A Multilayer Wiring Board (First Multilayer Wiring Board)
19A Top Surface of Multilayer Wiring Board 11A (First Surface)
19B Bottom Surface of Multilayer Wiring Board 11A (Second Surface)
15 Shield Case

### DETAILED DESCRIPTION OF PREFERRED EMBODIMENTS

### Exemplary Embodiment 1

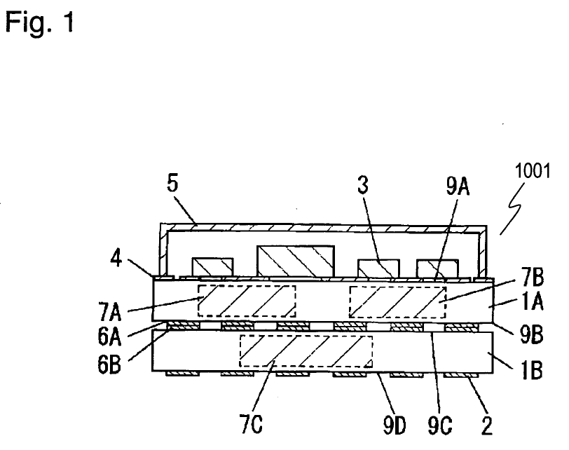

FIG. 1 is a sectional view of module 1001 according to Exemplary Embodiment 1 of the present invention. Module 1001 includes multilayer wiring board 1A, and multilayer wiring board 1B arranged under bottom surface 9B of multilayer wiring board 1A. Multilayer wiring board 1A has top surface 9A and bottom surface 9B opposite to top surface 9A. Multilayer wiring board 1B has top surface 9C and bottom surface 9D opposite to top surface 9C.

Multilayer wiring boards 1A and 1B are ceramic laminated circuit boards, such as low temperature co-fired ceramic (LTCC) boards.

Multilayer wiring board 1A has functional circuits 7A and 7B formed therein with a pattern in an inner layer portion of board 1A. Top surface 9A of multilayer wiring board 1A has component 3 mounted thereon. Grounding electrode 4 arranged on top surface 9A has shield case 5 arranged thereon. Shield case 4 covers component 9A and is connected to grounding electrode 4. Terminal electrode 6A for external connection is provided on bottom surface 9B of multilayer wiring board 1A.

Multilayer wiring board 1B has functional circuit 7C formed therein with a pattern in an inner layer portion of board 1B. Top surface 9C of multilayer wiring board 1B faces bottom surface 9B of multilayer wiring board 1A. Terminal electrode 6B is provided on top surface 9C of multilayer wiring board 1B. Terminal electrode 2 for external connection is provided on bottom surface 9D of board 1B.

Module 1001 is a front end module connected to an input port of a tuner receiving circuit. In this case, functional circuit 7A is a band-pass filter connected to an output port of an antenna. Component 3 is an amplifier connected to an output portion of the band-pass filter. Functional circuit 7B is a low-pass filter connected to an output port of the amplifier. Functional circuit 7C is a balun connected to an output port of the low-pass filter.

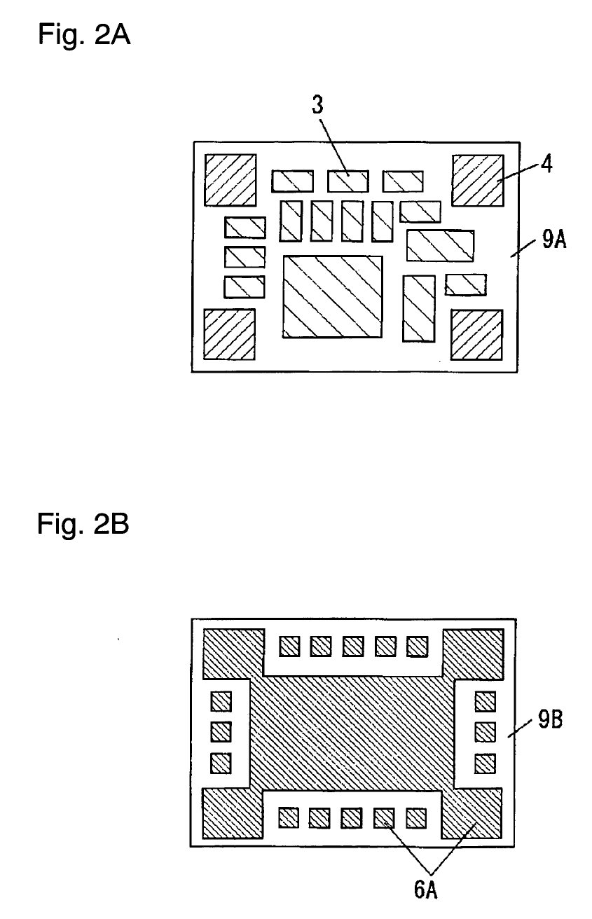

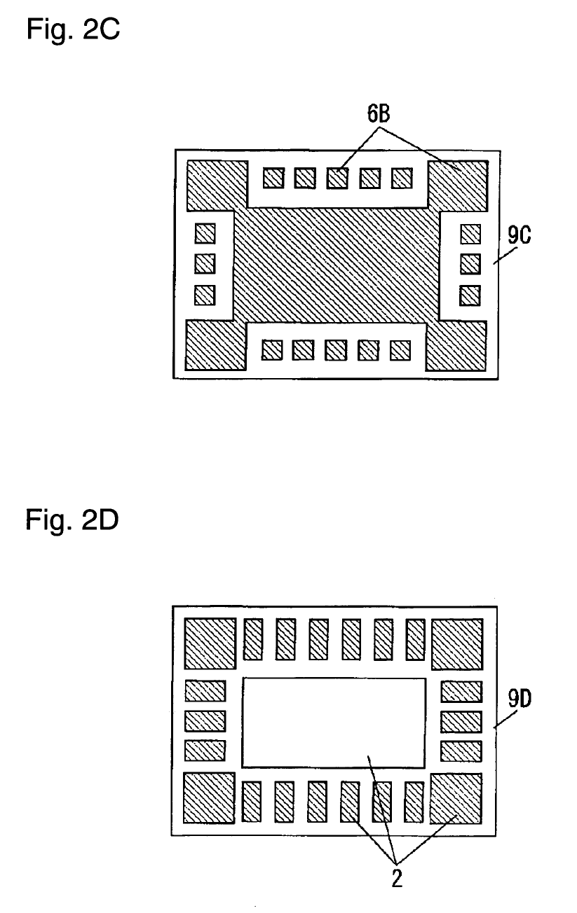

Conductor patterns formed on top surface 9A and bottom surface 9B of multilayer wiring board 1A and on top surface 9C and bottom surface 9D of multilayer wiring board 1B will be described. FIGS. 2A and 2B are top and bottom views of multilayer wiring board 1A of module 1001, respectively. Grounding electrodes 4 are arranged on four corners of top surface 9A of multilayer wiring board 1A. Components 3 are mounted at positions other than grounding electrode 4. Terminal electrodes 6A including plural electrodes provided along the four sides of bottom surface 9B of multilayer wiring board 1A and electrodes provided on bottom surface 9B from a central portion of bottom surface 9B to the four corners of bottom surface 9B.

FIGS. 2C and 2D are top and bottom views of multilayer wiring board 1B of module 1001, respectively. Terminal electrodes 6B are provided on top surface 9C of multilayer wiring board 1B at positions arranged to contact terminal electrodes 6A on bottom surface 9B of multilayer wiring board 1A shown in FIG. 2B, respectively.

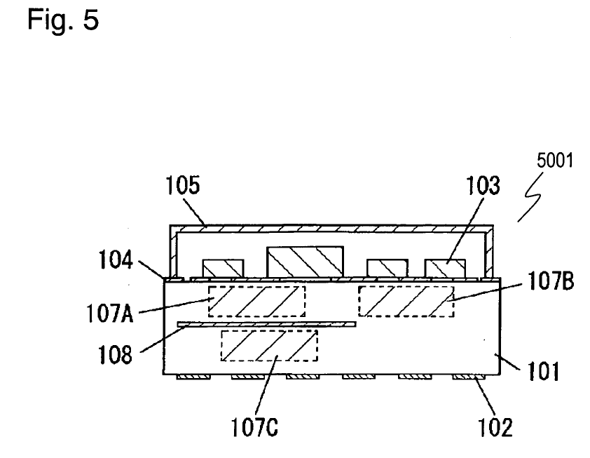

Multilayer wiring boards 1A and 1B are manufactured separately. Terminal electrodes 6A on multilayer wiring board 1A is electrically connected to terminal electrodes 6B on multilayer wiring board 1B with conductive adhesives, such as solder, respectively. This method allows multilayer wiring boards 1A and 1B can be inspected separately, namely, functional circuits 7A and 7C can be inspected separately, and functional circuits 7B and 7C can be inspected separately. Non-defective boards of multilayer wiring boards 1A and 1B are connected, thereby allowing module 1001 to be manufactured at a higher yield rate than a conventional multilayer wiring board 1 shown in FIG. 5.

If functional circuit 7C in multilayer wiring board 1B is not required, terminal electrodes 6A of multilayer wiring board 1A may be used as terminal electrodes for external connection. Module 1001 is thus easily changed in its functions and is mounted into various devices.

Module 1001 according to this embodiment includes two of multilayer wiring boards 1A and 1B, however, may be include three or more of the boards with the same effects.

### Exemplary Embodiment 2

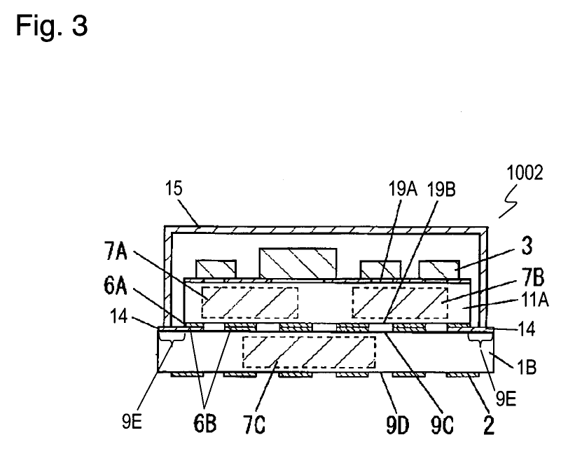

FIG. 3 is a sectional view of module 1002 according to Exemplary Embodiment 2 of the present invention. In FIG. 3, the same components as those of module 1001 according to Embodiment 1 shown in FIG. 1 are denoted by the same reference numerals, and their description will be omitted. Module 1002 includes multilayer wiring board 11A instead of multilayer wiring board 1A of module 1001 shown in FIG. 1, and shield case 15 instead of shield case 5. Multilayer wiring board 11A has top surface 19A and bottom surface 19B opposite to top surface 19A. Multilayer wiring board 11A has an area smaller than that of multilayer wiring board 1B. Top surface 9C of multilayer wiring board 1B thus has exposing portion 9E exposing outside multilayer wiring board 11A. In module 1002, grounding electrode 14 is provided on exposing portion 9E of top surface 9C of multilayer wiring board 1B. Shield case 15 covers component 3 and multilayer wiring board 11A is arranged and connected.

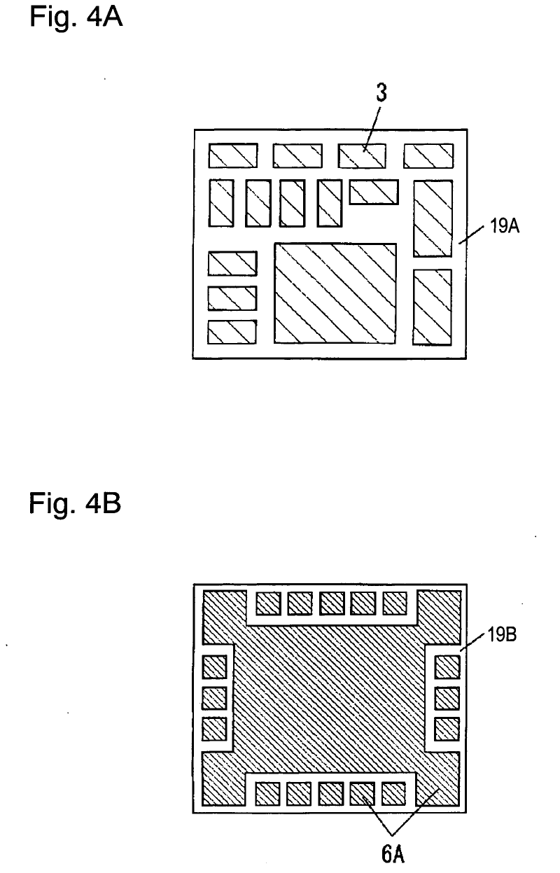

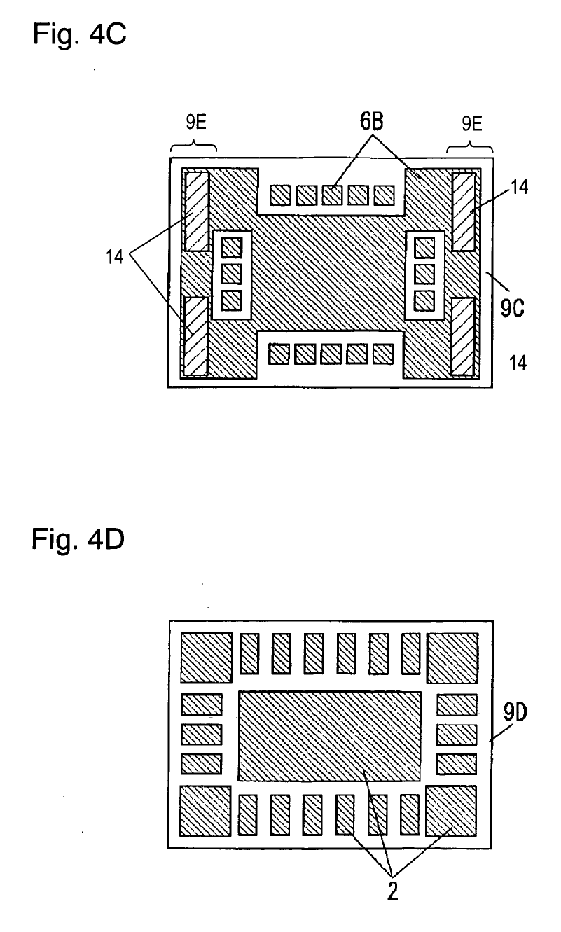

Conductor patterns provided on top surface 19A and bottom surface 19B of multilayer wiring board 11A and on top surface 9C and bottom surface 9D of multilayer wiring board 1B will be described. FIGS. 4A and 4B are top and bottom views of multilayer wiring board 11A of module 1002, respectively. Component 3 is mounted on top surface 19A of multilayer wiring board 11A.

FIGS. 4C and 4D are top and bottom views of multilayer wiring board 1B of module 1002, respectively. Terminal electrodes 6B are provided on top surface 9C of multilayer wiring board 1B. Terminal electrodes 6B contact terminal electrodes 6A provided on bottom surface 19B of multilayer wiring board 11A shown in FIG. 4B. Grounding electrodes 14 are provide on a periphery of terminal electrodes 6B. Grounding electrodes 14 is provide at exposing portion 9E on top surface 9C of multilayer wiring board 1B.

In module 1002, multilayer wiring boards 11A and 1B are manufactured separately, similarly to module 1001 according to Embodiment 1 shown in FIG. 1. Terminal electrodes 6A on multilayer wiring board 11A is electrically connected to terminal electrodes 6B on multilayer wiring board 1B with conductive adhesives, such as solder, respectively. This method allows multilayer wiring boards 11A and 1B, namely, functional circuits 7A and 7C are inspected separately, and functional circuits 7B and 7C are inspected separately. Non-defective boards of multilayer wiring boards 11A and 1B are connected, thereby allowing module 1002 to be manufactured at higher yield rate than a conventional multilayer wiring board 101 shown in FIG. 5.

If functional circuit 7C in multilayer wiring board 1B is not required, terminal electrodes 6A provided on multilayer wiring board 1A may be used as terminal electrodes for external connection. Module 1002 is thus easily changed in its functions and is mounted into various devices.

Module 1002 suppresses noises input into functional circuits 7A and 7B in multilayer wiring board 11A from sides of multilayer wiring board 11A. Shield case 15 is connected to grounding electrode 14 provided on top surface 9C of multilayer wiring board 1B, hence necessitating a grounding electrode on top surface 19A of multilayer wiring board 11A, thus allowing multilayer wiring board 11A to have a small size.

### INDUSTRIAL APPLICABILITY

A module according to the present invention can be manufactured at a high yield rate, and is useful for wireless communication devices, such as mobile phones, having high functions.

1. A module comprising:
a first multilayer wiring board having a first surface and a second surface opposite to the first surface;
a second multilayer wiring board having a third surface and a fourth surface opposite to the third surface, the third surface facing the second surface of the first multilayer wiring board;
a component mounted on the first surface of the first multilayer wiring board;
a first terminal electrode provided on the second surface of the first multilayer wiring board;
a second terminal electrode provided on the third surface of the second multilayer wiring board, the second terminal electrode being connected to the first terminal electrode; and
a terminal electrode provided on the fourth surface of the second multilayer wiring board.

2. The module of claim 1, wherein
the first multilayer wiring board has an area smaller than an area of the second multilayer wiring board, and
the third surface of the second multilayer wiring board has an exposing portion that exposes outside the first multilayer wiring board, said module further comprising:
a grounding electrode provided on the exposing portion of the third surface of the second multilayer wiring board; and
a shield case provided on the grounding electrode, the shield case being connected to the grounding electrode, the shield case covering the first multilayer wiring board.
